(19) United States
(12) Patent Application Publication
(10) Pub. No.: US 2026/0321323 A1
(43) Pub. Date: Oct. 15, 2026

(54) MEMORY DEVICE AND PROGRAMMING METHOD OF MEMORY DEVICE

(71) Applicant: SK hynix Inc., Gyeonggi-do (KR)

(72) Inventor: Eun Woo JO, Gyeonggi-do (KR)

(21) Appl. No.: 19/332,079

(22) Filed: Sep. 18, 2025

(30) Foreign Application Priority Data
Apr. 10, 2025 (KR) 10-2025-0046690

(51) Int. Cl. G11C 16/34; G11C 16/10

(52) U.S. Cl. CPC G11C 16/3459; G11C 16/10

(57) ABSTRACT

A memory device includes a plurality of memory cells and a peripheral circuit. The plurality of memory cells are connected to a plurality of word lines. The peripheral circuit performs, during a program period, a program operation on target memory cells connected to a selected word line among the plurality of word lines, applies, during a first intermediate period following the program period, a first intermediate voltage to the plurality of word lines, applies the first intermediate voltage to the selected word line and first unselected word lines among the plurality of word lines and applies a second intermediate voltage to second unselected word lines among the plurality of word lines during a second intermediate period following the first intermediate period, and performs, during a verification period following the second intermediate period, a verification operation on the target memory cells.

### CROSS-REFERENCES TO RELATED APPLICATION

The present application claims priority under 35 U.S.C. § 119(a) to Korean application number 10-2025-0046690 filed on Apr. 10, 2025, which is incorporated herein by reference in its entirety.

### BACKGROUND

### 1. Technical Field

Various embodiments generally relate to a memory device.

### 2. Related Art

Semiconductor devices are key components of electronic devices and have a wide range of modern applications, for example, semiconductor devices can be utilized in technologies such as computing, communications, artificial intelligence, and memory. A semiconductor device may consist of components such as transistors, diodes, and integrated circuits (ICs).

The program operation of a semiconductor memory device may be performed by applying various operation voltages to word lines connected to memory cells. The operation voltages may require a certain amount of time, that is, a settling time, to stabilize after reaching target voltage levels. If the settling time is insufficient, the target voltage levels may not be accurately reached, and thus the program operation may be incompletely performed. On the other hand, an excessively long settling time may cause a delay in the program operation, resulting in an increase in the overall program time. Therefore, technological developments to minimize the settling time while ensuring the accuracy of the program operation are desirable.

### SUMMARY

In an embodiment, a memory device may include a plurality of memory cells and a peripheral circuit. The plurality of memory cells may be connected to a plurality of word lines. The peripheral circuit may be configured to perform, during a program period, a program operation on target memory cells connected to a selected word line among the plurality of word lines, may be configured to apply, during a first intermediate period following the program period, a first intermediate voltage to the plurality of word lines, may be configured to, during a second intermediate period following the first intermediate period, apply the first intermediate voltage to the selected word line and first unselected word lines among the plurality of word lines and configured to apply a second intermediate voltage to second unselected word lines among the plurality of word lines, and may be configured to perform, during a verification period following the second intermediate period, a verification operation on the target memory cells.

In an embodiment, a programming method of a memory device may include: performing, during a program period, a program operation on target memory cells connected to a selected word line among a plurality of word lines; applying, during a first intermediate period following the program period, a first intermediate voltage to the plurality of word lines; during a second intermediate period following the first intermediate period, applying the first intermediate voltage to the selected word line and first unselected word lines among the plurality of word lines, and applying a second intermediate voltage to second unselected word lines among the plurality of word lines; and performing, during a verification period following the second intermediate period, a verification operation on the target memory cells.

In an embodiment, a memory device may include a plurality of memory cells and a peripheral circuit. The plurality of memory cells may be connected to a plurality of word lines. The peripheral circuit may be configured to, before performing a verification operation on target memory cells connected to a selected word line among the plurality of word lines, equalize, to a first intermediate voltage, first unselected word lines and the selected word line, the first unselected word lines being connected to memory cells in an erased state among the plurality of word lines, and may be configured to equalize, to a second intermediate voltage, second unselected word lines connected to memory cells in a programmed state among the plurality of word lines.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating a configuration of a memory device according to an embodiment of the present disclosure.

FIG. 2 is a circuit diagram illustrating a detailed configuration of a memory block according to an embodiment of the present disclosure.

FIG. 3 is a timing diagram for describing an operation of the memory device of FIG. 1, according to an embodiment of the present disclosure.

FIG. 4 is a timing diagram for describing an operation of the memory device of FIG. 1, according to an embodiment of the present disclosure.

FIG. 5 is a timing diagram for describing an operation of the memory device of FIG. 1, according to an embodiment of the present disclosure.

FIG. 6 is a flowchart illustrating a program operation of the memory device according to an embodiment of the present disclosure.

### DETAILED DESCRIPTION

Hereinafter, embodiments of the disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, such details may be omitted. As used herein, terms such as “comprises,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Such denotations as “first,” “second,” “A,” “B,” “(a),” and “(b)” may be used to describe components of the disclosure. These denotations are intended merely to distinguish one component from another, and are not intended to limit the nature, order, sequence, or number of the components.

Regarding the description of positional relationships between components, when two or more components are described as being “connected,” “coupled,” or “linked,” it should be understood that they may be directly “connected,” “coupled,” or “linked,” or may have an intervening component. Here, the intervening component may be included in one or more of the two or more components that are “connected,” “coupled,” or “linked” to each other.

When terms such as “after,” “next to,” “following,” “subsequent to” and “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

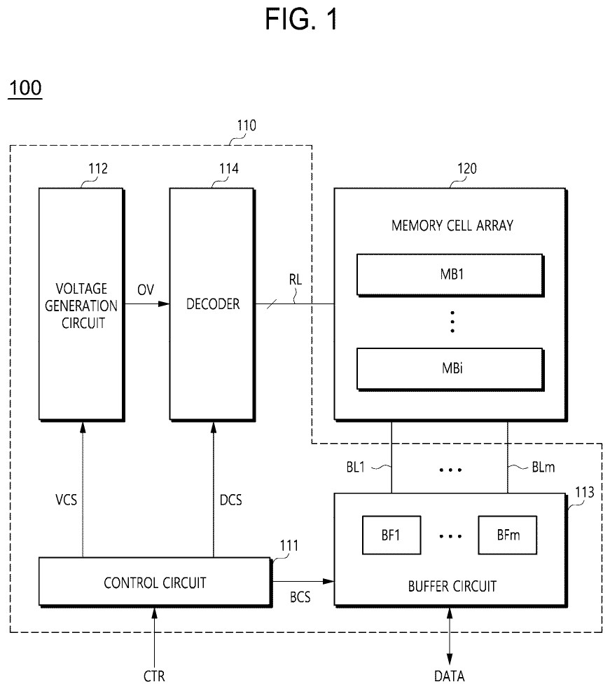

FIG. 1 is a block diagram illustrating a configuration of a memory device 100 according to an embodiment of the present disclosure.

Referring to FIG. 1, the memory device 100 may operate in response to a control from an external controller (not shown). Specifically, the memory device 100 may store data DATA received from the controller by performing a program operation in response to an external signal CTR received from the controller. In addition, the memory device 100 may output the stored data DATA to the controller by performing a read operation in response to the external signal CTR received from the controller.

The memory device 100 may include a peripheral circuit 110 and a memory cell array 120.

The peripheral circuit 110 may store data in the memory cell array 120 and read data from the memory cell array 120. The peripheral circuit 110 may include a control circuit 111, a voltage generation circuit 112, a buffer circuit 113, and a decoder 114.

The control circuit 111 may control operations of a voltage generation circuit 112, a buffer circuit 113, and a decoder 114 to perform internal operations of the memory device 100, such as program operations, read operations, erase operations, and the like, in response to the external signal CTR. For example, to control the voltage generation circuit 112, the control circuit 111 may generate a voltage control signal VCS and output it to the voltage generation circuit 112. To control the buffer circuit 113, the control circuit 111 may generate a buffer control signal BCS and output it to the buffer circuit 113. To control the decoder 114, the control circuit 111 may generate a decoder control signal DCS and output it to the decoder 114.

The voltage generation circuit 112 may generate various voltages in response to the voltage control signal VCS and transmit the voltages to the buffer circuit 113, decoder 114, and other circuits of the memory device 100. For example, the voltage generation circuit 112 may output voltages OV (a program voltage, a program pass voltage, an equalizing voltage, a turn-on voltage, a first intermediate voltage, a second intermediate voltage, a verification voltage, one or more verification pass voltages, and so on) to the decoder 114 through one or more voltage nodes VN.

The buffer circuit 113 may be coupled to the memory cell array 120 through bit lines BL1 to BLm. The buffer circuit 113 may include buffers BF1 to BFm coupled to the bit lines BL1 to BLm, respectively. The buffers BF1 to BFm may be coupled with memory cells (not shown) included in the memory cell array 120 through the bit lines BL1 to BLm. The buffers BF1 to BFm may receive and store data DATA to be stored in the memory cells from the controller. The buffers BF1 to BFm may store the data DATA read from the memory cells for output to the controller. The buffers BF1 to BFm may operate simultaneously in response to the buffer control signal BCS, such that the memory cells coupled with the bit lines BL1 to BLm, respectively, may be accessed simultaneously.

The decoder 114 may be coupled to the memory cell array 120 through row lines RL. The decoder 114 may apply the voltages OV delivered from the voltage generation circuit 112 to the row lines RL in response to the decoder control signal DCS. The row lines RL may include one or more drain selection lines, a plurality of word lines, and one or more source selection lines, each connected to memory blocks MB1 to MBi, as will be described later.

The memory cell array 120 may include a plurality of memory blocks MB1 to MBi. The memory blocks MB1 to MBi may include memory cells in which the data DATA is stored. The memory blocks MB1 to MBi may share the bit lines BL1 to BLm. A memory block may be a unit on which an erase operation is performed.

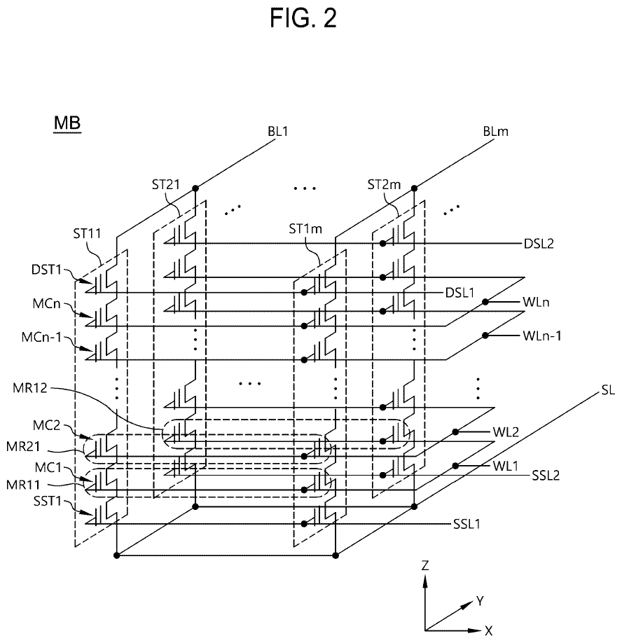

FIG. 2 is a circuit diagram illustrating a detailed configuration of a memory block MB according to an embodiment of the present disclosure. Each of the memory blocks MB1 to MBi of FIG. 1 may be configured similarly to the memory block MB.

Referring to FIG. 2, the memory block MB may include strings ST11 to ST1m, and ST21 to ST2m. Each of the strings ST11 to ST1m, ST21 to ST2m may extend along a vertical direction (Z direction). Within the memory block MB, m strings may be arranged in a row direction (X direction). In FIG. 2, two strings are shown arranged in a column direction (Y direction), but this is for illustrative purposes only, and three or more strings may be arranged in the column direction (Y direction).

The strings ST11 to ST1m, and ST21 to ST2m may be configured identically. For example, the string ST11 may include a source selection transistor SST, memory cells MC1 to MCn, and a drain selection transistor DST, coupled in series with each other between the source line SL and the bit line BL1. A source of the source selection transistor SST may be coupled to the source line SL, and a drain of the drain selection transistor DST may be coupled to the bit line BL1. The memory cells MC1 to MCn may be coupled in series with each other between the source selection transistor SST1 and the drain selection transistor DST1. In an embodiment, a plurality of source selection transistors may be coupled in series between the source line SL and the memory cell MC1. In an embodiment, a plurality of drain selection transistors may be coupled in series between the bit line BL1 and the memory cell MCn.

Source selection transistors at the same position in a vertical direction may be configured as shown below. Specifically, the gates of the source selection transistors of strings arranged in the same row may be coupled to the same source selection line. For example, the gates of the source selection transistors of strings ST11 to ST1m in a first row may be coupled to a source selection line SSL1. For example, the gates of the source selection transistors of a second row of strings ST21 to ST2m may be coupled to a source selection line SSL2.

In an embodiment, source selection transistors of two or more rows of strings may be coupled in common to a single source selection line. For example, the source selection transistors of the first and second rows of strings ST11 to ST1m, ST21 to ST2m may be coupled in common to one source selection line, and the source selection transistors of the third and fourth rows of strings may be coupled in common to one source selection line.

Drain selection transistors at the same position in a vertical direction may be configured as shown below. Specifically, the gates of the drain selection transistors of strings arranged in the same row may be coupled to the same drain selection line. For example, the gates of the drain selection transistors of the strings ST11 to ST1m of the first row may be coupled to the drain selection line DSL1. For example, the gates of the drain selection transistors of the second row of the strings ST21 to ST2m may be coupled to the drain selection line DSL2.

Strings arranged in the same column may be coupled to the same bit line. For example, strings ST11, ST21 in a first column may be coupled to the bit line BL1. For example, strings ST1m, ST2m in an m-th column may be coupled to the bit line BLm.

Gates of memory cells at the same position in a vertical direction may be coupled to the same word line. For example, in strings ST11 to ST1m and ST21 to ST2m, memory cells that are at the same position in a direction perpendicular to the memory cell MC1 may be coupled to the word line WL1.

Among the memory cells, memory cells coupled to the same word line in the same row may constitute one memory region. For example, memory cells coupled to the word line WL1 in the first row may constitute one memory region MR11. For example, memory cells coupled to the word line WL1 in the second row may constitute one memory region MR12. For example, memory cells coupled to word line WL2 in the first row may constitute one memory region MR21. Depending on the number of rows, each word line may be coupled to multiple memory regions. The memory cells constituting one memory region may be accessed simultaneously.

In an embodiment, the memory block MB may be further coupled to at least one dummy word line other than the word lines WL1 to WLn. In this instance, the memory block MB may further include dummy memory cells coupled to dummy word lines.

In the following description, a selected word line may be a word line among the word lines WL1 to WLn that is connected to target memory cells on which a program operation is performed. The remaining word lines among the word lines WL1 to WLn, other than the selected word line, may be referred to as unselected word lines.

The word lines WL1 to WLn may be sequentially programmed according to a predetermined program sequence. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. The program sequence may be, for example, from the word line WL1 to the word line WLn, or in the reverse order. When the program sequence is from the word line WL1 to the word line WLn and the selected word line is the i-th word line, memory cells connected to the word lines from the word line WL1 to the (i+1)-th word line may be in a programmed state (that is, a state where data DATA is stored), and memory cells connected to the word lines from the (i+1)-th word line to the word line WLn may be in an erased state. In the following description, word lines subsequent to the selected word line in the program sequence, for example, from the (i+1)-th word line to the word line WLn, may be referred to as first unselected word lines, and word lines preceding the selected word line in the program sequence, for example, from the word line WL1 to the (i+1)-th word line, may be referred to as second unselected word lines.

Briefly describing a program operation for target memory cells, the peripheral circuit 110 may apply a program voltage to a selected word line and apply a program pass voltage to unselected word lines. Accordingly, the threshold voltages of the target memory cells may increase in response to the program voltage, thereby storing the data DATA in the target memory cells.

To verify whether the data DATA has been properly stored in the target memory cells, the peripheral circuit 110 may perform a verification operation. Specifically, the peripheral circuit 110 may apply a verification voltage to the selected word line and apply predetermined voltages (which may include a turn-on voltage and a verification pass voltage, as will be described later) to the unselected word lines to turn on memory cells. A target memory cell having a threshold voltage lower than the verification voltage (that is, a target memory cell where the storage of the data DATA is incomplete) may be turned on in response to the verification voltage, and the state of a bit line connected to the target memory cell may change. A target memory cell having a threshold voltage higher than the verification voltage (that is, a target memory cell where the storage of the data DATA is complete) may be turned off in response to the verification voltage, and the state of a bit line connected to the target memory cell may not change. Accordingly, by sensing the state of the bit line (for example, the current amount and/or voltage level of the bit line), it may be determined whether the data DATA has been stored in the target memory cell, and the program operation may proceed again according to the determination result.

Referring again to FIG. 1, the peripheral circuit 110 may perform a program operation on target memory cells connected to a selected word line among the plurality of word lines WL1 to WLn during a program period, apply a first intermediate voltage to the plurality of word lines WL1 to WLn during a first intermediate period following the program period, apply the first intermediate voltage to the selected word line and first unselected word lines among the plurality of word lines WL1 to WLn and apply a second intermediate voltage to second unselected word lines among the plurality of word lines WL1 to WLn during a second intermediate period following the first intermediate period, and perform a verification operation on the target memory cells during a verification period following the second intermediate period.

In an embodiment, during the verification operation, the peripheral circuit 110 may apply the first intermediate voltage to the first unselected word lines, apply the verification voltage to the selected word line, and apply one or more verification pass voltages to the second unselected word lines.

In an embodiment, the second intermediate voltage may be higher than the first intermediate voltage.

In an embodiment, the second intermediate voltage may be the lowest verification pass voltage among the one or more verification pass voltages.

In an embodiment, the second intermediate voltage may be lower than the one or more verification pass voltages.

As will be described in detail below, according to the present disclosure, by equalizing the first unselected word lines and the second unselected word lines to different first and second intermediate voltages respectively, according to the states of memory cells connected to the unselected word lines before the verification period, the settling time of the word lines WL1 to WLn during the verification period may be reduced, and as a result, the program performance may be improved.

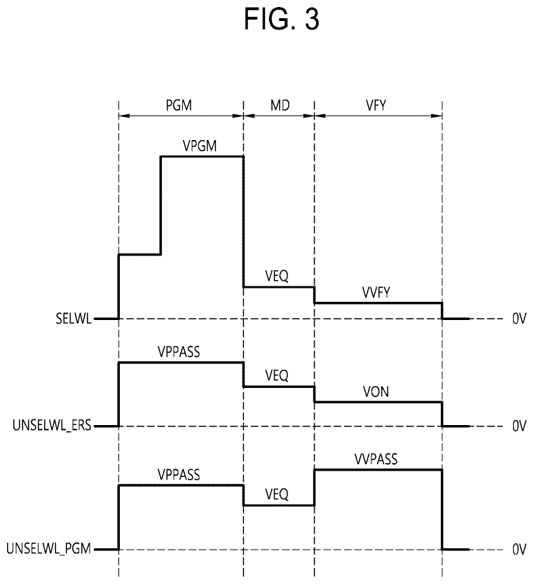

FIG. 3 is a timing diagram for describing an operation of the memory device 100 of FIG. 1, according to an embodiment of the present disclosure.

Referring to FIG. 3, during a program period PGM, the peripheral circuit 110 may apply a program voltage VPGM to a selected word line SELWL. In addition, the peripheral circuit 110 may apply a program pass voltage VPPASS, which is lower than the program voltage VPGM, to first unselected word lines UNSELWL_ERS and second unselected word lines UNSELWL_PGM.

During an intermediate period MD following the program period PGM, the peripheral circuit 110 may apply an equalizing voltage VEQ to the selected word line SELWL, the first unselected word lines UNSELWL_ERS, and the second unselected word lines UNSELWL_PGM. In other words, during the intermediate period MD, the word lines WL1 to WLn may be equalized by the equalizing voltage VEQ.

During a verification period VFY following the intermediate period MD, the peripheral circuit 110 may apply a verification voltage VVFY to the selected word line SELWL. In addition, the peripheral circuit 110 may apply a turn-on voltage VON, which is lower than the verification pass voltage VVPASS, to the first unselected word lines UNSELWL_ERS. Further, the peripheral circuit 110 may apply the verification pass voltage VVPASS to the second unselected word lines UNSELWL_PGM.

When the program voltage VPGM and the program pass voltage VPPASS are discharged to the equalizing voltage VEQ without being discharged to a ground voltage 0V during the intermediate period MD, a discharge time and a consumption current may be reduced, and a negative channel boosting effect may be suppressed, thereby improving overall program performance. However, as the equalizing voltage VEQ increases, the settling time of the second unselected word lines UNSELWL_PGM during the verification period VFY may decrease, while the settling times of the selected word line SELWL and the first unselected word lines UNSELWL_ERS may increase. Conversely, as the equalizing voltage VEQ decreases, the settling times of the selected word line SELWL and the first unselected word lines UNSELWL_ERS during the verification period VFY may decrease, while the settling time of the second unselected word lines UNSELWL_PGM may increase.

Further, applying the turn-on voltage VON, which is lower than the verification pass voltage VVPASS, to the first unselected word lines UNSELWL_ERS during the verification period VFY may be to reduce a back pattern dependency. Specifically, as memory cells connected to the word lines WL1 to WLn are sequentially programmed according to a program sequence, the resistance of channels connected to each of the bit lines BL1 to BLm may increase. As a result, the amount of current flowing through channels connected to the bit lines BL1 to BLm during the verification period VFY may differ from the amount of current flowing during a read operation when all the memory cells connected to the word lines WL1 to WLn are in a programmed state, leading to a decrease in the accuracy of the verification operation and degradation of program performance. Therefore, to make the amount of current flowing during the verification period VFY similar to the amount of current flowing during the read operation, the turn-on voltage VON, which is lower than the verification pass voltage VVPASS, may be applied to the first unselected word lines UNSELWL_ERS during the verification period VFY.

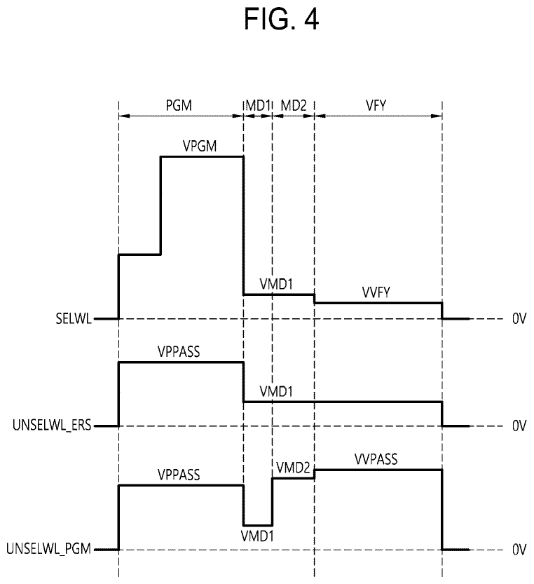

FIG. 4 is a timing diagram for describing an operation of the memory device 100 of FIG. 1, according to an embodiment of the present disclosure.

Referring to FIG. 4, in a program period PGM, the peripheral circuit 110 may apply the program voltage VPGM to the selected word line SELWL. In addition, the peripheral circuit 110 may apply the program pass voltage VPPASS, which is lower than the program voltage VPGM, to the first unselected word lines UNSELWL_ERS and the second unselected word lines UNSELWL_PGM.

During a first intermediate period MD1 following the program period PGM, the peripheral circuit 110 may apply a first intermediate voltage VMD1 to the selected word line SELWL, the first unselected word lines UNSELWL_ERS, and the second unselected word lines UNSELWL_PGM. In other words, during the first intermediate period MD1, the word lines WL1 to WLn may be equalized to the first intermediate voltage VMD1.

During a second intermediate period MD2 following the first intermediate period MD1, the peripheral circuit 110 may apply the first intermediate voltage VMD1 to the selected word line SELWL and the first unselected word lines UNSELWL_ERS, and apply a second intermediate voltage VMD2 to the second unselected word lines UNSELWL_PGM. In other words, during the second intermediate period MD2, the selected word line SELWL and the first unselected word lines UNSELWL_ERS may be equalized to the first intermediate voltage VMD1, and the second unselected word lines UNSELWL_PGM may be equalized to the second intermediate voltage VMD2. The second intermediate voltage VMD2 may be higher than the first intermediate voltage VMD1. The second intermediate voltage VMD2 may be lower than the verification pass voltage VVPASS.

During a verification period VFY following the second intermediate period MD2, the peripheral circuit 110 may apply the first intermediate voltage VMD1 to the first unselected word lines UNSELWL_ERS, apply the verification voltage VVFY to the selected word line SELWL, and apply the verification pass voltage VVPASS to the second unselected word lines UNSELWL_PGM.

In an embodiment, during the verification period VFY, the peripheral circuit 110 may sequentially apply one or more verification voltages to the selected word line SELWL.

According to an embodiment of the present disclosure, by providing the second intermediate period MD2, the peripheral circuit 110 may apply the first intermediate voltage VMD1 with a lower level than the equalizing voltage VEQ shown in FIG. 3. Accordingly, the settling times of the selected word line SELWL and the first unselected word lines UNSELWL_ERS during the verification period VFY may be reduced. If the first intermediate voltage VMD1 is at a level equal to the turn-on voltage VON shown in FIG. 3, settling of the first unselected word lines UNSELWL_ERS during the verification period VFY may become unnecessary, and the back pattern dependency may also be effectively suppressed. Furthermore, because the second intermediate voltage VMD2 is applied to the second unselected word lines UNSELWL_PGM before the verification pass voltage VVPASS during the verification period VFY, the settling time of the second unselected word lines UNSELWL_PGM during the verification period VFY may also be reduced. As a result, programming performance may be improved.

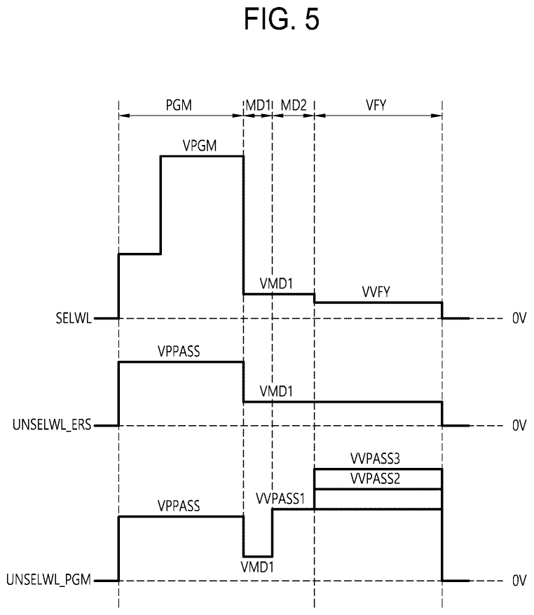

FIG. 5 is a timing diagram for describing an operation of the memory device 100 of FIG. 1, according to an embodiment of the present disclosure.

Referring to FIG. 5, operations during a program period PGM and a first intermediate period MD1 may be similar to those described with reference to FIG. 3 or FIG. 4. Hereinafter, content overlapping with previously described content may be omitted.

During a second intermediate period MD2, the peripheral circuit 110 may apply the first intermediate voltage VMD1 to the selected word line SELWL and the first unselected word lines UNSELWL_ERS, and apply a first verification pass voltage VVPASS1 to the second unselected word lines UNSELWL_PGM. In other words, the first verification pass voltage VVPASS1, which is the lowest among the first to third verification pass voltages VVPASS1 to VVPASS3, may be applied as the second intermediate voltage VMD2 in FIG. 4.

During a verification period VFY, the peripheral circuit 110 may apply the first to third verification pass voltages VVPASS1 to VVPASS3 to the second unselected word lines UNSELWL_PGM. Specifically, the second unselected word lines UNSELWL_PGM may be grouped into first to third groups according to different characteristics, and the peripheral circuit 110 may apply the first verification pass voltage VVPASS1 to the first group of the second unselected word lines UNSELWL_PGM, apply the second verification pass voltage VVPASS2, which is higher than the first verification pass voltage VVPASS1, to the second group of the second unselected word lines UNSELWL_PGM, and apply the third verification pass voltage VVPASS3, which is higher than the second verification pass voltage VVPASS2, to the third group of the second unselected word lines UNSELWL_PGM. In an embodiment, the number of verification pass voltages may be less than or greater than three.

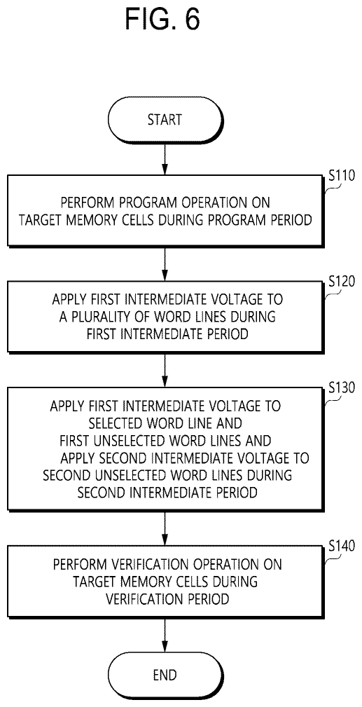

FIG. 6 is a flowchart illustrating a program operation of the memory device according to an embodiment of the present disclosure.

Referring to FIG. 6, in operation S110, the peripheral circuit 110 may perform a program operation on target memory cells connected to the selected word line SELWL among the plurality of word lines WL1 to WLn during the program period PGM. The program operation may include applying the program voltage VPGM to the selected word line SELWL and applying the program pass voltage VPPASS to the first unselected word lines UNSELWL_ERS and the second unselected word lines UNSELWL_PGM.

In operation S120, the peripheral circuit 110 may apply the first intermediate voltage VMD1 to the plurality of word lines WL1 to WLn during the first intermediate period MD1.

In operation S130, the peripheral circuit 110 may apply the first intermediate voltage VMD1 to the selected word line SELWL and the first unselected word lines UNSELWL_ERS, and apply the second intermediate voltage VMD2 to the second unselected word lines UNSELWL_PGM during the second intermediate period MD2.

In operation S140, the peripheral circuit 110 may perform a verification operation on the target memory cells during the verification period VFY. The verification operation may include applying the first intermediate voltage VMD1 to the first unselected word lines UNSELWL_ERS, applying the verification voltage VVFY to the selected word line SELWL, and applying the one or more verification pass voltages to the second unselected word lines UNSELWL_PGM.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A memory device comprising:
a plurality of memory cells connected to a plurality of word lines; and
a peripheral circuit configured to:
perform, during a program period, a program operation on target memory cells connected to a selected word line among the plurality of word lines;
apply, during a first intermediate period following the program period, a first intermediate voltage to the plurality of word lines;
during a second intermediate period following the first intermediate period, apply the first intermediate voltage to the selected word line and first unselected word lines among the plurality of word lines, and apply a second intermediate voltage to second unselected word lines among the plurality of word lines; and
perform, during a verification period following the second intermediate period, a verification operation on the target memory cells.

2. The memory device of claim 1, wherein the first unselected word lines are connected to memory cells in an erased state.

3. The memory device of claim 1, wherein the second unselected word lines are connected to memory cells in a programmed state.

4. The memory device of claim 1, wherein, when performing the program operation, the peripheral circuit is configured to:
apply a program voltage to the selected word line; and
apply a program pass voltage to the first unselected word lines and the second unselected word lines.

5. The memory device of claim 1, wherein, when performing the verification operation, the peripheral circuit is configured to:
apply the first intermediate voltage to the first unselected word lines;
apply a verification voltage to the selected word line; and
apply one or more verification pass voltages to the second unselected word lines.

6. The memory device of claim 1, wherein the second intermediate voltage is higher than the first intermediate voltage.

7. The memory device of claim 1, wherein the second intermediate voltage is a lowest verification pass voltage among one or more verification pass voltages.

8. The memory device of claim 1, wherein the second intermediate voltage is lower than one or more verification pass voltages.

9. A programming method of a memory device, the method comprising:
performing, during a program period, a program operation on target memory cells connected to a selected word line among a plurality of word lines;
applying, during a first intermediate period following the program period, a first intermediate voltage to the plurality of word lines;
during a second intermediate period following the first intermediate period, applying the first intermediate voltage to the selected word line and first unselected word lines among the plurality of word lines, and applying a second intermediate voltage to second unselected word lines among the plurality of word lines; and
performing, during a verification period following the second intermediate period, a verification operation on the target memory cells.

10. The programming method of claim 9, wherein the first unselected word lines are connected to memory cells in an erased state.

11. The programming method of claim 9, wherein the second unselected word lines are connected to memory cells in a programmed state.

12. The programming method of claim 9, wherein performing the program operation comprises:
applying a program voltage to the selected word line; and
applying a program pass voltage to the first unselected word lines and the second unselected word lines.

13. The programming method of claim 9, wherein performing the verification operation comprises:
applying the first intermediate voltage to the first unselected word lines;
applying a verification voltage to the selected word line; and
applying one or more verification pass voltages to the second unselected word lines.

14. The programming method of claim 9, wherein the second intermediate voltage is higher than the first intermediate voltage.

15. The programming method of claim 9, wherein the second intermediate voltage is a lowest verification pass voltage among one or more verification pass voltages.

16. The programming method of claim 9, wherein the second intermediate voltage is lower than one or more verification pass voltages.

17. A memory device comprising:
a plurality of memory cells connected to a plurality of word lines; and
a peripheral circuit configured to, before performing a verification operation on target memory cells connected to a selected word line among the plurality of word lines:
equalize, to a first intermediate voltage, first unselected word lines and the selected word line, the first unselected word lines being connected to memory cells in an erased state among the plurality of word lines; and
equalize, to a second intermediate voltage, second unselected word lines connected to memory cells in a programmed state among the plurality of word lines.

18. The memory device of claim 17, wherein the second intermediate voltage is higher than the first intermediate voltage.

19. The memory device of claim 17, wherein, during the verification operation, the second intermediate voltage is a lowest verification pass voltage among one or more verification pass voltages applied to the second unselected word lines.

20. The memory device of claim 17, wherein, during the verification operation, the second intermediate voltage is lower than one or more verification pass voltages applied to the second unselected word lines.
